(19) United States
(12) Patent Application Publication
(10) Pub. No.: US 2026/0169052 A1
(43) Pub. Date: Jun. 18, 2026

(54) Workload-Aware Control Architecture for Semiconductor Devices

(71) Applicant: Google LLC, Mountain View, CA (US)

(72) Inventors: Mohsen Heidarinejad, San Jose, CA (US); Arpit Mittal, San Jose, CA (US)

(73) Assignee: Google LLC, Mountain View, CA (US)

(21) Appl. No.: 18/978,836

(22) Filed: Dec. 12, 2024

(51) Int. Cl. G01R 31/26; G06F 1/18; G06F 1/20; H01M 10/633

(52) U.S. Cl. CPC G01R 31/2642; G06F 1/189; G06F 1/206; H01M 10/633

(57) ABSTRACT

Aspects of workload-aware control architectures for semiconductor devices are disclosed. For example, a control unit receives power target values from a power consumption analyzing unit and estimated temperature gradients from a temperature analyzing unit each coupled with an element of a semiconductor device. The power consumption analyzing unit determines the power target values based on power consumption of the element and the temperature analyzing unit determines the estimated temperature gradients based on temperature in combination with a temperature history of the element. The control unit generates revised power targets and temperature targets based on the received power target values, the estimated temperature gradients, and a usage history. The usage history may include a current workload and/or a workload history of the element and may be provided by a machine-learned model or artificial intelligence. The revised power target and temperature target values are dynamically generated to optimize performance.

### BACKGROUND

Semiconductor devices are widely used throughout the world in various electronic devices. It is estimated that almost 80% of the world's population owns a mobile phone, which is one type of electronic device. One semiconductor device used within electronic devices is a system-on-a-chip (SoC), which may include various elements, such as a central processing unit (CPU), a graphic processing unit (GPU), an accelerated processing unit (APU), an audio processing unit, and a tensor processing unit (TPU).

The various elements of a semiconductor device (e.g., CPU, GPU) within an electronic device may cause a rise in temperature within the semiconductor device, which may apply stress or reduce performance of the semiconductor device when the temperature is too high. To address these high temperatures, a thermal control policy may be applied to the elements of a semiconductor in an effort to control potential thermal issues. These thermal control policies, however, often fail to adequately control the semiconductor device.

### SUMMARY

This document describes systems and techniques directed at a workload-aware control architecture for semiconductor devices, which may overcome or reduce the disadvantages of applying a conventional fixed thermal control policy. For example, the workload-aware control architecture may apply temperature and power consumption policies at least partially based on the workload of the semiconductor device.

Aspects of a workload-aware control architecture for semiconductor devices are disclosed. For example, a control unit receives power target values from a power consumption analyzing unit and estimated temperature gradients from a temperature analyzing unit each coupled with element(s) of a semiconductor device. The power consumption analyzing unit determines the power target values based on power consumption of the elements, and the temperature analyzing unit determines the estimated temperature gradients based on temperature in combination with a temperature history of the elements. The control unit generates revised power targets and temperature targets based on the received power target values, the estimated temperature gradients, and a usage history. The usage history may include a current workload and/or a workload history of the elements and may be provided by a machine-learned model or artificial intelligence. The revised power target and temperature target values are dynamically generated to optimize performance.

In some aspects, the techniques described herein relate to a method including receiving, at a control unit, a first power target value and a second power target value from a power consumption analyzing unit. The first power target value and the second power target value are determined based, at least in part, on a first power consumption of a first element associated with a semiconductor device and a second power consumption of a second element associated with the semiconductor device. The method including receiving, at the control unit, a first estimated temperature gradient and a second estimated temperature gradient from a temperature analyzing unit. The first estimated temperature gradient is determined based on a first temperature of the first element and a temperature history of the first element, and the second estimated temperature gradient is determined based on a second temperature of the second element and a temperature history of the second element.

The method including determining, by the control unit, a first revised power target value and a first temperature target value. The first revised power target value and the first temperature target value are determined based on the first power target value, the first estimated temperature gradient, and a usage history of the semiconductor device. The method including applying the first revised power target value and the first temperature target value to the first element, the applying effective to control a first operating frequency of the first element. The method including determining, by the control unit, a second revised power target value and a second temperature target value. The second revised power target value and the second temperature target value are determined based on the second power target value, the second estimated temperature gradient, and the usage history of the semiconductor device. The method including applying the second revised power target value and the second temperature target value to the second element, the applying effective to control a second operating frequency of the second element.

In some aspects, the techniques described herein relate to a system including a first element and a second element of a semiconductor device, the first element having a first power consumption and a first temperature and the second element having a second power consumption and a second temperature. The system including a power consumption analyzing unit coupled to the first element and the second element, the power consumption analyzing unit configured to determine a metric based on the first power consumption and the second power consumption, the metric being applied to the first power consumption and the second power consumption to determine a first power target value and a second power target value. The system including a temperature analyzing unit coupled to the first element and the second element, the temperature analyzing unit configured to determine a first estimated temperature gradient and a second estimated temperature gradient. The first estimated temperature gradient is determined based on a first temperature of the first element and a temperature history of the first element, and the second estimated temperature gradient is determined based on a second temperature of the second element and a temperature history of the second element. The system including a control unit coupled with the power consumption analyzing unit and the temperature analyzing unit. The control unit is configured to determine a first revised power target value and a first temperature target value based on the first power target value, the first estimated temperature gradient, and a usage history of the semiconductor device. The control unit is also configured to determine a second revised power target value and a second temperature target value based on the second power target value, the second estimated temperature gradient, and the usage history of the semiconductor device.

The system including a first temperature controller and a first power controller coupled with the control unit and the first element. The first temperature controller is configured to apply a first temperature-based operating frequency to the first element based on the first temperature and the first temperature target value. The first power controller is configured to apply a first power-based operating frequency to the first element based on the first power consumption and the first revised power target value. The system including a second temperature controller and a second power controller coupled with the control unit and the second element. The second temperature controller is configured to apply a second temperature-based operating frequency to the second element based on the second temperature and the second temperature target value. The second power controller is configured to apply a second power-based operating frequency to the second element based on the second power consumption and the second revised power target value.

In some aspects, the techniques described herein relate to a system including a first element and a second element of a semiconductor device, the first element having a first power consumption and a first temperature and the second element having a second power consumption and a second temperature. The system including a power consumption analyzing unit coupled to the first element and the second element. The power consumption analyzing unit is configured to determine a metric based on the first power consumption and the second power consumption, the metric being applied to the first power consumption and the second power consumption to determine a first power target value and a second power target value. The system including a temperature analyzing unit coupled to the first element and the second element. The temperature analyzing unit is configured to determine a first estimated temperature gradient and a second estimated temperature gradient. The first estimated temperature gradient is determined based on a first temperature of the first element and a temperature history of the first element, and the second estimated temperature gradient is determined based on a second temperature of the second element and a temperature history of the second element.

The system including a control unit coupled with the power consumption analyzing unit and the temperature analyzing unit. The control unit is configured to determine a first revised power target value and a first temperature target value based on the first power target value, the first estimated temperature gradient, and a usage history of the semiconductor device. The control unit is also configured to determine a second revised power target value and a second temperature target value based on the second power target value, the second estimated temperature gradient, and the usage history of the semiconductor device. The system including a temperature controller coupled with the control unit, the first element, and the second element. The temperature controller is configured to apply a first temperature-based operating frequency to the first element based on the first temperature and the first temperature target value and to apply a second temperature-based operating frequency to the second element based on the second temperature and the second temperature target value. The system including a power controller coupled with the control unit, the first element, and the second element. The power controller is configured to apply a first power-based operating frequency to the first element based on the first power consumption and the first revised power target value and to apply a second power-based operating frequency to the second element based on the second power consumption and the second revised power target value.

This Summary is provided to introduce simplified concepts of workload-aware control architectures for semiconductor devices, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at workload-aware control architectures for semiconductor devices are described in this document with reference to the following drawings, in which the use of same numbers in different instances may indicate similar features or components.

FIG. 1-1 illustrates an example system in which aspects of a workload-aware control architecture for a semiconductor device can be implemented.

FIG. 1-2 illustrates an example system in which aspects of a workload-aware control architecture for a semiconductor device can be implemented.

FIG. 2 illustrates an example power consumption analyzing unit that may be implemented in a workload-aware control architecture for a semiconductor device.

FIG. 3-1 illustrates an example configuration of controllers and semiconductor elements in which aspects of a workload-aware control architecture for a semiconductor device can be implemented.

FIG. 3-2 illustrates an example configuration of controllers and semiconductor elements in which aspects of a workload-aware control architecture for a semiconductor device can be implemented.

FIG. 4 illustrates an example operating environment in which aspects of a workload-aware control architecture for a semiconductor device can be implemented.

FIG. 5 illustrates an integrated circuit component in which aspects of a workload-aware control architecture for a semiconductor device can be implemented.

FIG. 6 illustrates an example electronic device having internal hardware configurations for a workload-aware control architecture for a semiconductor device in accordance with one or more implementations.

FIG. 7 is a flowchart of a method of a workload-aware control architecture for a semiconductor device.

FIG. 8 is a flowchart of a method of a workload-aware control architecture for a semiconductor device.

### DETAILED DESCRIPTION

### Overview

Electronic devices often include a semiconductor device that applies a fixed thermal control policy to various elements of the semiconductor device. The fixed thermal control policy may be implemented to prevent the operation of an element from creating a thermal issue (e.g., overheating) of the electronic device. The fixed thermal control policy may throttle an element (e.g., lower an operating frequency) to reduce power consumption of the element and prevent a temperature of the element from exceeding a temperature threshold. However, the fixed thermal control policy may not be optimized for the current usage of the electronic device and/or may not be optimized for a predicted future usage of the electronic device.

For example, the control policy may be adequate to prevent a thermal issue during an average use of an electronic device but may be too severe for a light use of the electronic device. Likewise, the control policy may not be severe enough for heavy use of the electronic device. A light user of a mobile phone may only use the mobile phone to text and make phone calls. In such a case, a fixed thermal control policy may be too severe resulting in diminished user experience. As another example, a heavy user may use applications and/or play games on the mobile phone that use a high amount of resources. Here, a fixed thermal control policy may not be severe enough.

Furthermore, a fixed thermal control policy is not optimized for the operation of an electronic device. For example, the workload of an electronic device can change depending on the time of day, the user, and/or the location of the electronic device. The workload on the electronic device affects whether a fixed thermal control policy provides an improved user experience or a diminished user experience. A fixed thermal control policy does not take into account the workload history of the electronic device, which may be a factor in optimizing the control policies applied to the semiconductor elements of an electronic device.

To this end, this document describes systems and techniques directed at workload-aware control architectures for semiconductor devices.

The techniques described herein may include a control unit that generates dynamic control policies to control the operation frequency of various elements of a semiconductor device. The control unit may utilize a usage history to optimize the dynamic control policies. For example, a machine-learned model or artificial intelligence may indicate a current workload and/or a workload history of various elements of the semiconductor device. The control unit may utilize the current workload and/or a workload history in determining the dynamic control policies. The control unit may utilize the usage history in combination with estimated temperature gradients, received from a temperature analyzing unit, and power target values, received from a power consumption analyzing unit.

The dynamic control policies may include revised power target values and temperature target values for respective elements of the semiconductor device. The dynamic control policies may be communicated to the respective elements effective to control an operating frequency of the respective elements. The dynamic control policies may be communicated to an element by one or more controllers coupled to the element. For example, a power controller and a temperature controller may be coupled to an element and each may apply a target value. The element may be configured to apply a lowest operating frequency based on a lower target value received from controllers coupled with the element. Alternatively, an accumulator may receive more than one target value and communicate only the target value to the element that will result in the lowest operating frequency.

The following discussion describes operating environments, techniques that may be employed in the operating environments, and example methods. Although techniques using and apparatuses for workload-aware control architectures for semiconductor devices are described, it is to be understood that the subject of the appended claims is not necessarily limited to the specific features or methods described. Rather, the specific features and methods are disclosed as example implementations and reference is made to the operating environment by way of example only.

### Example Systems and Operational Schemes

A workload-aware architecture for a semiconductor device is able to generate dynamic control policies to optimize the performance of a semiconductor device. Conventional fixed control policies are created for one set of operating conditions and may unnecessarily hamper the performance of the semiconductor device and/or an electronic device utilizing the semiconductor device. Conversely, in some situations, fixed control policies may not apply sufficient power consumption and/or thermal controls that may lead to thermal issues and/or catastrophic performance issues. The workload-aware architecture dynamically determines control policies based on usage history (e.g., current workload, past workload) as well as the present temperature and power consumption of elements of the semiconductor device. Thus, the workload-aware architecture is able to optimize performance of semiconductor devices as well as electronic devices utilizing the semiconductor devices.

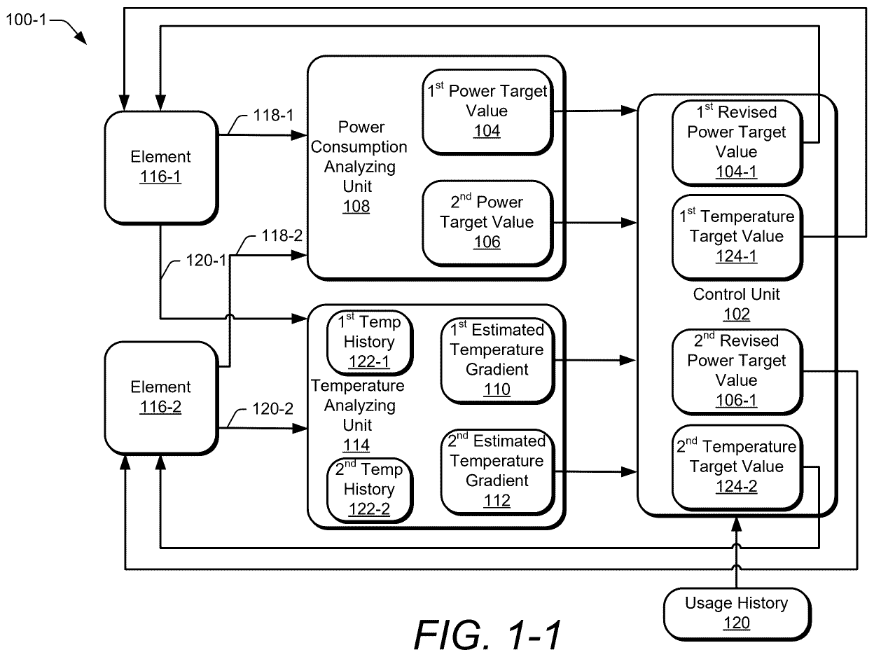

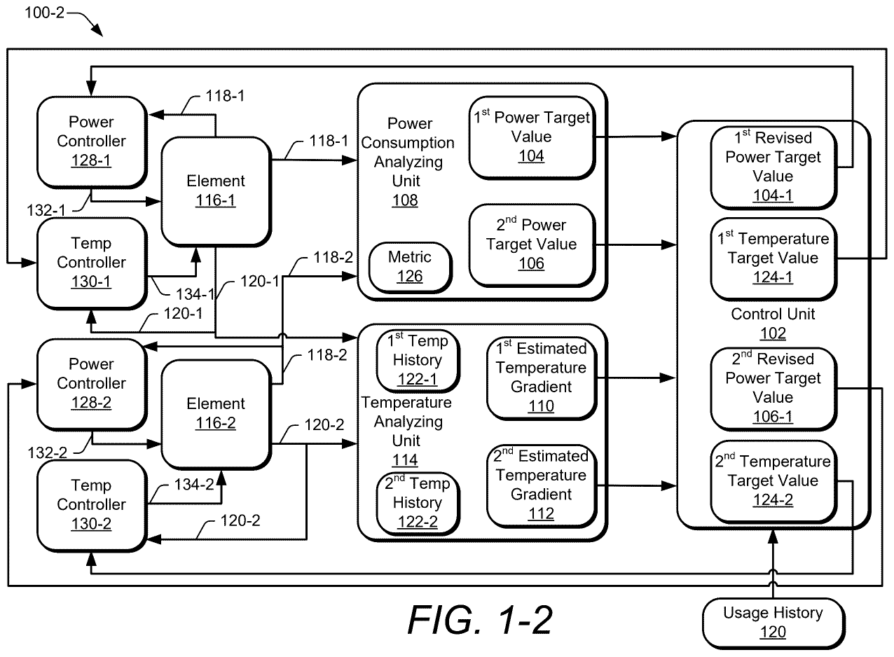

FIG. 1-1 illustrates an example system 100-1 in which aspects of workload-aware control architectures for a semiconductor device can be implemented. The system 100-1 includes a control unit 102. The control unit 102 is configured to determine dynamic controls based at least partially on workload as discussed below. The control unit 102 is coupled with a power consumption analyzing unit 108 and a temperature analyzing unit 114. The control unit 102 is also coupled with a first element 116-1 of a semiconductor device and a second element 116-2 of the semiconductor device. The first element 116-1 may be any component (e.g., CPU, GPU, TPU, or the like) of the semiconductor device that consumes power and may lead to a rise in temperature due to operation of the first element 116-1. Likewise, the second element 116-2 may be any component (e.g., CPU, GPU, TPU, or the like) of the semiconductor device that consumes power and may lead to a rise in temperature due to operation of the second element 116-2.

The first and second elements 116-1 and 116-2 may be any component of the semiconductor device that consumes power. For example, the first and second elements 116-1 and 116-2 may be a processor that consumes power and may lead to a rise in temperature. The processor may be a CPU, GPU, TPU, or the like. The first and second elements 116-1 and 116-2 may instead be a non-processing element, such as a sensor or display. For example, the sensor may be an optical sensor, radar sensor, proximity sensor, or the like. The first and second elements 116-1 and 116-2 may be any component of a semiconductor device that consumes power and may lead to a rise in temperature due to operation.

The first element 116-1 is coupled with the power consumption analyzing unit 108 and the temperature analyzing unit 114. Likewise, the second element 116-2 is coupled with the power consumption analyzing unit 108 and the temperature analyzing unit 114. The first element 116-1 provides a first power consumption value 118-1 to the power consumption analyzing unit 108 and a first temperature value 120-1 to the temperature analyzing unit 114. The first power consumption value 118-1 may indicate a present power consumption of the first element 116-1, and the first temperature value 120-1 may indicate a present temperature of the first element 116-1. The second element 116-2 provides a second power consumption value 118-2 to the power consumption analyzing unit 108 and a second temperature value 120-2 to the temperature analyzing unit 114. The second power consumption value 118-2 may indicate a present power consumption of the second element 116-2, and the second temperature value 120-2 may indicate a present temperature of the second element 116-2.

The power consumption analyzing unit 108 receives the first power consumption value 118-1 from the first element 116-1 and the second power consumption value 118-2 from the second element 116-2. Based on the received first and second power consumption values 118-1 and 118-2, the power consumption analyzing unit 108 determines a first power target value (1^{st} Power Target Value) 104 and a second power target value (2^{nd} Power Target Value) 106. Various procedures may be applied based on the first and second power consumption values 118-1 and 118-2 to determine the first power target value 104 and the second power target value 106. For example, the power consumption analyzing unit 108 may weigh the first and second power consumption values 118-1 and 118-2 to determine the first power target value 104 and the second power target value 106. In other aspects, the power consumption analyzing unit 108 may apply a filter and/or an algorithm to the first and second power consumption values 118-1 and 118-2 to determine the first power target value 104 and the second power target value 106 as would be appreciated by one of ordinary skill in the art having the benefit of this disclosure.

The power consumption analyzing unit 108 is configured to determine the first power target value 104 and the second power target value 106. The power consumption analyzing unit 108 is configured to provide the first and second power target values 104 and 106 to the control unit 102. The power consumption analyzing unit 108 may be comprised of various elements to determine the first power target value 104 and the second power target value 106. For example, the power consumption analyzing unit 108 may be comprised of a power sensor and a controller. As yet another example, the power consumption analyzing unit 108 may be a processor configured to determine the first power target value 104 and the second power target value 106 based on received inputs from the first and second elements 116-1 and 116-2. The power consumption analyzing unit 108 may be a controller that includes logic configured to determine the first power target value 104 and the second power target value 106 based on received inputs from the first and second elements 116-1 and 116-2.

The temperature analyzing unit 114 receives the first temperature value 120-1 from the first element 116-1 and the second temperature value 120-2 from the second element 116-2. Based on the received first and second temperatures values 120-1 and 120-2 as well as a first temperature history (1^{st} Temp History) 122-1 and a second temperature history (2^{nd} Temp History) 122-2, the temperature analyzing unit 114 determines a first estimated temperature gradient (1^{st} Estimated Temperature Gradient) 110 and a second estimated temperature gradient (2^{nd} Estimated Temperature Gradient) 112. The first temperature history 122-1 is a record of prior temperatures for the first element 116-1. Likewise, the second temperature history 122-2 is a record of prior temperatures for the second element 116-2. The first temperature history 122-1 may be previous first temperature values 120-1 of the first element 116-1 that have been communicated to the temperature analyzing unit 114 over a specified time period (e.g., specified timescale). Likewise, the second temperature history 122-2 may be previous second temperature values 120-2 of the second element 116-2 that have been communicated to the temperature analyzing unit 114 over the specified time period. The temperature analyzing unit 114 may be configured to store previously communicated first and second temperature values 120-1 and 120-2 in memory. The memory may be integral to the temperature analyzing unit 114. In other aspects, the memory may be located outside of the temperature analyzing unit 114. In other aspects, one or more temperature sensors, coupled with the first and second elements 116-1 and 116-2, may be configured to communicate the first and second temperature histories 122-1 and 122-2 to the temperature analyzing unit 114.

The temperature analyzing unit 114 uses the first temperature value 120-1 and the first temperature history 122-1 to determine the first estimated temperature gradient 110 of the first element 116-1. Likewise, the temperature analyzing unit 114 uses the second temperature value 120-2 and the second temperature history 122-2 to determine the second estimated temperature gradient 112 of the second element 116-2. The temperature analyzing unit 114 communicates the first estimated temperature gradient 110 and the second estimated temperature gradient 112 to the control unit 102. The first estimated temperature gradient 110 predicts the change in temperature of the first element 116-1 for a specified time period. Likewise, the second estimated temperature gradient 112 predicts the change in temperature of the second element 116-2 for a specified time period.

Various procedures may be applied to determine the first estimated temperature gradient 110 and the second estimated temperature gradient 112 as would be appreciated by one of ordinary skill in the art having the benefit of this disclosure. For example, the temperature analyzing unit 114 may estimate the future change in temperature simply based on the present temperature value in view of the temperature history. In other aspects, the temperature analyzing unit 114 may apply a filter and/or an algorithm to determine the first estimated temperature gradient 110 and the second estimated temperature gradient 112.

The temperature analyzing unit 114 is configured to determine the first estimated temperature gradient 110 and the second estimated temperature gradient 112 and provides the estimated temperature gradients 110 and 112 to the control unit 102. The temperature analyzing unit 114 may be comprised of various elements to determine the estimated temperature gradients 110 and 112. For example, the temperature analyzing unit 114 may be comprised of a temperature monitor and a controller. As yet another example, the temperature analyzing unit 114 may be a processor configured to determine the estimated temperature gradients 110 and 112 based on received temperature inputs from the first and second elements 116-1 and 116-2. The temperature analyzing unit 114 may be a controller that includes logic configured to determine the estimated temperature gradients 110 and 112 based on received temperature inputs from the first and second elements 116-1 and 116-2.

The control unit 102 receives the first power target value 104 and the second power target value 106 from the power consumption analyzing unit 108. In combination with a usage history 120 and the first power target value 104 and the second power target value 106, the control unit 102 determines a first revised power target value (1^{st} Revised Power Target Value) 104-1 and a second revised power target value (2^{nd} Revised Power Target Value) 106-1, which may be communicated to the first element 116-1 and the second element 116-2 respectively. The first revised power target value 104-1 may effectively change an operation frequency of the first element 116-1 to control the power consumption of the first element 116-1 according to the first revised power target value 104-1 dynamically generated by the control unit 102 in view of the workload of the semiconductor device. The second revised power target value 106-1 may effectively change an operation frequency of the second element 116-2 to control the power consumption of the second element 116-2 according to the second revised power target value 106-1 dynamically generated by the control unit 102 in view of the workload of the semiconductor device.

The usage history 120 may be provided to the control unit 102 by a machine-learned model and/or artificial intelligence. A machine-learned model may be used to monitor the usage of the semiconductor device and/or the electronic device over a predetermined timescale. The machine-learned model may be a standard neural-network-based model with corresponding layers required for processing input features like fixed-side vectors, text embeddings, or variable length sequences. The machine-learned model may be implemented as one or more of a support vector machine (SVM), a recurrent neural network (RNN), a convolutional neural network (CNN), a dense neural network (DNN), one or more heuristics, other machine-learning techniques, a combination thereof, and so forth.

The usage history 120 may include a current workload of an electronic device and/or a semiconductor device of the electronic device. The usage history 120 may also include the workload of the electronic device and/or the semiconductor device for a predetermined time period. The control unit 102 revises the first and second power target values 104 and 106 based on the received usage history 120. The usage history 120 provides the control unit 102 awareness of the current workload and/or the workload for a predetermined timescale.

The control unit 102 receives the first estimated temperature gradient 110 and the second estimated temperature gradient 112 from the temperature analyzing unit 114. In combination with the usage history 120 and the first estimated temperature gradient 110 and the second estimated temperature gradient 112, the control unit 102 determines a first temperature target value (1^{st} Temperature Target Value) 124-1 and a second temperature target value (2^{nd} Temperature Target Value) 124-2, which may be communicated to the first element 116-1 and the second element 116-2 respectively. The first temperature target value 124-1 may effectively change the operation frequency of the first element 116-1 to control the temperature of the first element 116-1 according to the first temperature target value 124-1 dynamically generated by the control unit 102 in view of the workload of the semiconductor device. The second temperature target value 124-2 may effectively change the operation frequency of the second element 116-2 to control the temperature of the second element 116-2 according to the second temperature target value 124-2 dynamically generated by the control unit 102 in view of the workload of the semiconductor device.

The control unit 102 may be a controller configured to determine the outputs (e.g., the first revised power target value 104-1, the second revised power target value 106-1, the first temperature target value 124-1, the second temperature target value 124-2) based on the received inputs (e.g., the first power target value 104, the second power target value 106, the first estimated temperature gradient 110, the second estimated temperature gradient 112, the usage history 120). In one aspect, the control unit 102 may be a processor configured to determine the outputs based on the received inputs. The control unit 102 may be a machine-learned model trained to provide the outputs based on the received inputs. The machine-learned model may be configured to analyze the semiconductor device and/or electronic device to determine the usage history 120 as would be appreciated by one of ordinary skill in the art having the benefit of this disclosure.

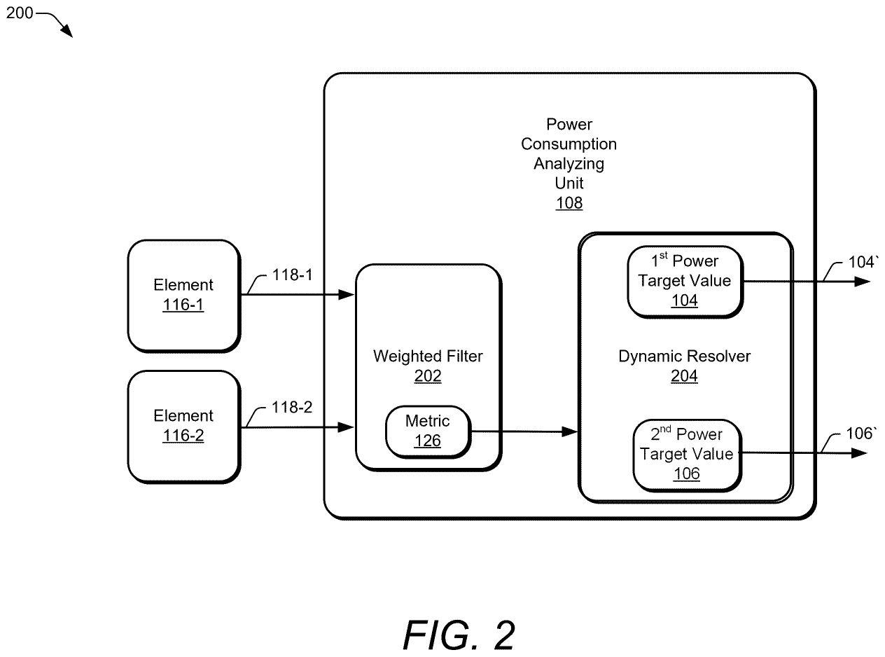

The first element 116-1 receives both the first revised power target value 104-1 and the first temperature target value 124-1, which each may be effective to change the operation frequency of the first element 116-1. However, one of the received targets (e.g., the first revised power target value 104-1 and the first temperature target value 124-1) may set the operating frequency lower (e.g., lesser) than the other received target. Thus, the first element 116-1 may be configured to set the operating frequency to the lower operating frequency based on the first revised power target value 104-1 and the first temperature target value 124-1. Likewise, the second element 116-2 may be configured to set the operating frequency of the second element 116-2 to the lower operating frequency between the received second revised power target value 106-1 and the second temperature target value 124-2. The first and second elements 116-1 and 116-2, power consumption analyzing unit 108, temperature analyzing unit 114, and control unit 102 are shown for illustrative purposes and may be varied as would be appreciated by one of ordinary skill in the art having the benefit of this disclosure. For example, the system 100-1 may include more or less than two elements (e.g., first element 116-1, second element 116-2) coupled with one or more power consumption analyzing unit(s) 108, temperature analyzing unit(s) 114, and control unit(s) 102. The system 100-1 of FIG. 1-1 illustrates aspects of a workload-aware control architecture for semiconductor devices. FIG. 1-2 illustrates another system in which aspects of a workload-aware control architecture for semiconductor devices can be implemented.

FIG. 1-2 illustrates an example system 100-1 that includes a control unit 102 coupled with a power consumption analyzing unit 108 and a temperature analyzing unit 114. The control unit 102 is also coupled with a first power controller 128-1, a first temperature controller (Temp Controller) 130-1, a second power controller 128-2, and a second temperature controller (Temp Controller) 130-2. The first power controller 128-1 and first temperature controller 130-1 are associated (e.g., coupled) with a first element 116-1 of a semiconductor device, and the second power controller 128-2 and second temperature controller 130-2 are associated (e.g., coupled) with a second element 116-2 of the semiconductor device. The first power controller 128-1 is configured to control a power consumption of the first element 116-1, and the first temperature controller 130-1 is configured to control a temperature of the first element 116-1. The second power controller 128-2 is configured to control a power consumption of the second element 116-2, and the second temperature controller 130-2 is configured to control a temperature of the second element 116-2.

The control unit 102 of FIG. 1-2 operates similarly to the control unit 102 of FIG. 1-1. For example, the control unit 102 dynamically generates a first revised power target value (1^{st} Revised Power Target Value) 104-1 and second revised power target value (2^{nd} Revised Power Target Value) 104-2 based on a usage history 120 and a first power target value (1^{st} Power Target Value) 104 and second power target value (2^{nd} Power Target Value) 106 received from the power consumption analyzing unit 108. Likewise, the control unit 102 dynamically generates a first temperature target value (1^{st} Temperature Target Value) 124-1 and a second temperature target value (2^{nd} Temperature Target Value) 124-2 based on the usage history 120 and a first estimated temperature gradient (1^{st} Estimated Temperature Gradient) 110 and a second estimated temperature gradient (2^{nd} Estimated Temperature Gradient) 112 received from the temperature analyzing unit 114. However, the first power controller 128-1 and the first temperature controller 130-1 are coupled between the first element 116-1 and the control unit 102, and the second power controller 128-2 and the second temperature controller 130-2 are coupled between the second element 116-2 and the control unit 102. Thus, the first revised power target value 104-1 and the first temperature target value 124-1 are communicated to the first power controller 128-1 and the first temperature controller 130-1, respectively, and the second revised power target value 106-1 and the second temperature target value 124-2 are communicated to the second power controller 128-2 and the second temperature controller 130-2, respectively.

The first power controller 128-1 is configured to communicate a first power-based operating frequency 132-1, based on the first revised power target value 104-1 received from the control unit 102 and feedback 118-1 (e.g., first power consumption value) from the first element 116-1, to the first element 116-1 effective to control an operating frequency of the first element 116-1. The first temperature controller 130-1 is configured to communicate a first temperature-based operating frequency 134-1, based on the first temperature target value 124-1 received from the control unit 102 and feedback 120-1 (e.g., first temperature value) from the first element 116-1, to the first element 116-1 effective to control the operating frequency of the first element 116-1. The first element 116-1 may be configured to operate at the operating frequency that is the lowest operating frequency between the received first power-based operating frequency 132-1 and the first temperature-based operating frequency 134-1.

Likewise, the second power controller 128-2 is configured to communicate a second power-based operating frequency 132-2, based on the second revised power target value 106-1 received from the control unit 102 and feedback 118-2 (e.g., second power consumption value) from the second element 116-2, to the second element 116-2 effective to control an operating frequency of the second element 116-2. The second temperature controller 130-2 is configured to communicate a second temperature-based operating frequency 134-2, based on the second temperature target value 124-2 received from the control unit 102 and feedback 120-2 (e.g., second temperature value) from the second element 116-2, to the second element 116-2 effective to control the operating frequency of the second element 116-2. The second element 116-2 may be configured to operate at the operating frequency that is the lowest operating frequency between the received second power-based operating frequency 132-2 and the received second temperature-based operating frequency 134-2.

The power consumption analyzing unit 108 may determine a metric 126 based on the first power consumption value 118-1 received from the first element 116-1 and the second power consumption value 118-2 received from the second element 116-2. The metric 126 may be used to determine the first power target value 104 and the second power target value 106. For example, the metric 126 may be determined by weighting the first power target value 104 and the second power target value 106. The weighting may be a linear ratio of the first power consumption value 118-1 and the second power consumption value 118-2. In other aspects, an algorithm may be applied to the first power consumption value 118-1 and the second power consumption value 118-2 to determine the metric 126. The type of element may affect the weighting algorithm. In other aspects, the higher power consumption may be weighted with the lower power consumption receiving no weighting value. In one aspect, the power consumption analyzing unit 108 may weight the first power consumption and/or the second power consumption if the power consumption exceeds a predetermined threshold. In an aspect, the power consumption analyzing unit 108 may apply a first weight if the power consumption exceeds the predetermined threshold and a second weight if the power consumption does not exceed the predetermined threshold. The system 100-2 shown in FIG. 1-2 may be used to apply aspects of a workload-aware control architecture for semiconductor devices that enable the dynamic generation of controls rather than applying fixed thermal controls to elements of a semiconductor device. FIG. 2 illustrates one aspect of a power consumption analyzing unit 108 that may be used in a workload-aware architecture for semiconductor devices.

FIG. 2 illustrates a portion of a system 200 that may be implemented in a workload-aware architecture. The system 200 includes a power consumption analyzing unit 108 coupled with a first element 116-1 and a second element 116-2 of a semiconductor device. The first element 116-1 provides a first power consumption value 118-1 to the power consumption analyzing unit 108 and the second element 116-2 provides a second power consumption value 118-2 to the power consumption analyzing unit 108. The power consumption analyzing unit 108 includes a weighted filter 202. The weighted filter 202 generates a metric 126 based on weighting the first power consumption value 118-1 and the second power consumption value 118-2. The weighted filter 202 provides the metric 126 to a dynamic resolver 204 within the power consumption analyzing unit 108. The dynamic resolver 204 applies the metric 126 to the first power consumption value 118-1 and the second power consumption value 118-2 to determine a first power target value (1^{st} Power Target Value) 104 and a second power target value (2^{nd} Power Target Value) 106. The first power target value 104 and the second power target value 106 may then be communicated to a control unit (not shown in FIG. 2) as indicated by arrows 104 ′ and 106′. The power consumption analyzing unit 108 may be coupled with one or more elements of a semiconductor device. FIGS. 3-1 and 3-2 illustrate different configurations of elements of a semiconductor device.

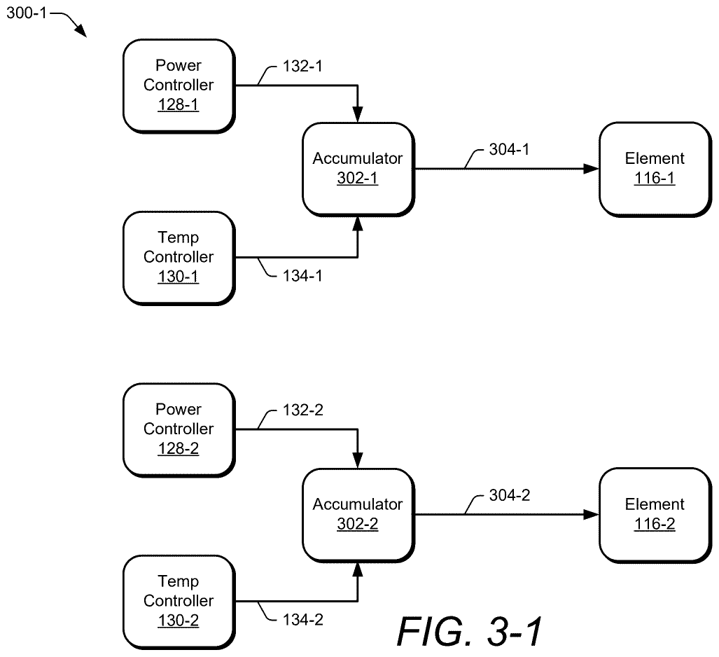

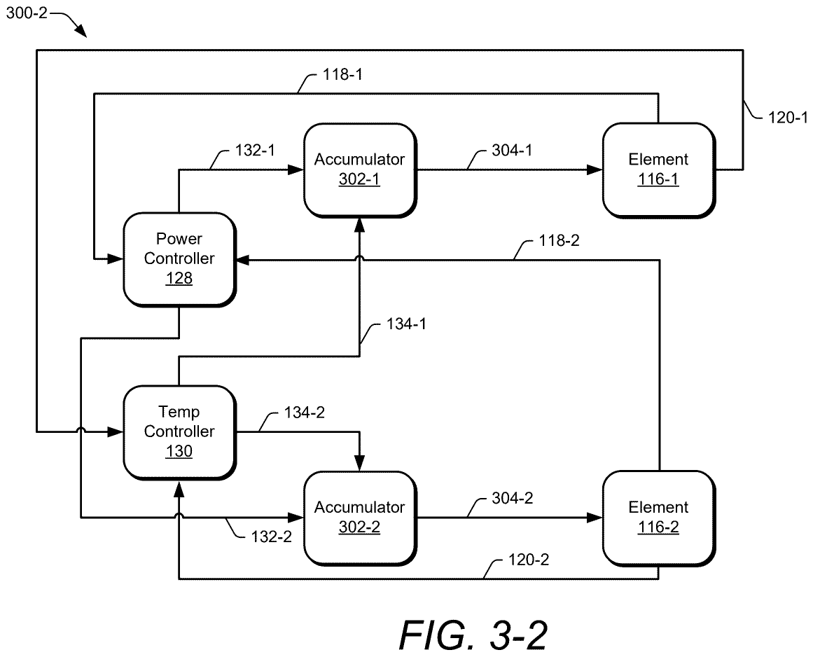

FIG. 3-1 illustrates an example configuration 300-1 of controllers (e.g., first power controller 128-1, first temperature controller 130-1, second power controller 128-2, second temperature controller 130-2) and semiconductor elements (e.g., first element 116-1, second element 116-2) in which aspects of a workload-aware control architecture for a semiconductor device can be implemented. A first accumulator 302-1 may be coupled between the first element 116-1 and the first power controller 128-1 and the first temperature controller (Temp Controller) 130-1. A second accumulator 302-2 may be coupled between the second element 116-2 and the second power controller 128-2 and the second temperature controller (Temp Controller) 130-2. As discussed above, the first power controller 128-1 may be configured to communicate a first power-based operating frequency 132-1 to the first element 116-1 and the first temperature controller 130-1 may be configured to communicate a first temperature-based operating frequency 134-1 to the first element 116-1. Instead of being communicated directly to the first element 116-1, the first power-based operating frequency 132-1 and the first temperature-based operating frequency 134-1 may be communicated to the first accumulator 302-1. Likewise, the second power-based operating frequency 132-2 and the second temperature-based operating frequency 134-2 may be communicated from the second power controller 128-2 and second temperature controller 130-2 to the second accumulator 302-2 instead of directly to the second element 116-2. The first and second accumulators 302-1 and 302-2 may be configured to communicate a single of the received operating frequencies (e.g., first power-based operating frequency 132-1, first temperature-based operating frequency 134-1, second power-based operating frequency 132-2, second temperature-based operating frequency 134-2) 304-1 and 304-2 to the respective element (e.g., first element 116-1, second element 116-2). In other words, the first and second accumulators 302-1 and 302-2 may be configured to communicate only the operating frequency 304-1 and 304-2 that is the lowest operating frequency (e.g., the lesser of the two operating frequencies) to the respective element (e.g., first element 116-1, second element 116-2).

FIG. 3-2 illustrates an example configuration 300-2 in which a power controller 128 and a temperature controller (Temp Controller) 130 are coupled to more than one element (e.g., first element 116-1, second element 116-2). The power controller 128 is configured to individually control a power consumption of the first element 116-1 and individually control a power consumption of the second element 116-2. The temperature controller 130 is configured to individually control a temperature of the first element 116-1 and individually control a temperature of the second element 116-2. A first accumulator 302-1 is coupled between the first element 116-1 and the power controller 128 and the temperature controller 130. A second accumulator 302-2 is coupled between the second element 116-2 and the power controller 128 and the temperature controller 130. As discussed above, the first and second accumulators 302-1 and 302-2 may be configured to pass a single operating frequency (e.g., first power-based operating frequency 132-1, first temperature-based operating frequency 134-1, second power-based operating frequency 132-2, second temperature-based operating frequency 134-2) to the element (e.g., first element 116-1, second element 116-2) coupled with the respective accumulator (e.g., first accumulator 302-1, second accumulator 302-2).

The example aspects illustrated in FIGS. 1-1, 1-2, 2, 3-1, and 3-2 may be implemented by a workload-aware control architecture to generate dynamic controls for elements of a semiconductor device as would be appreciated by one of ordinary skill in the art having the benefit of this disclosure.

### Example Environments and Electronic Devices

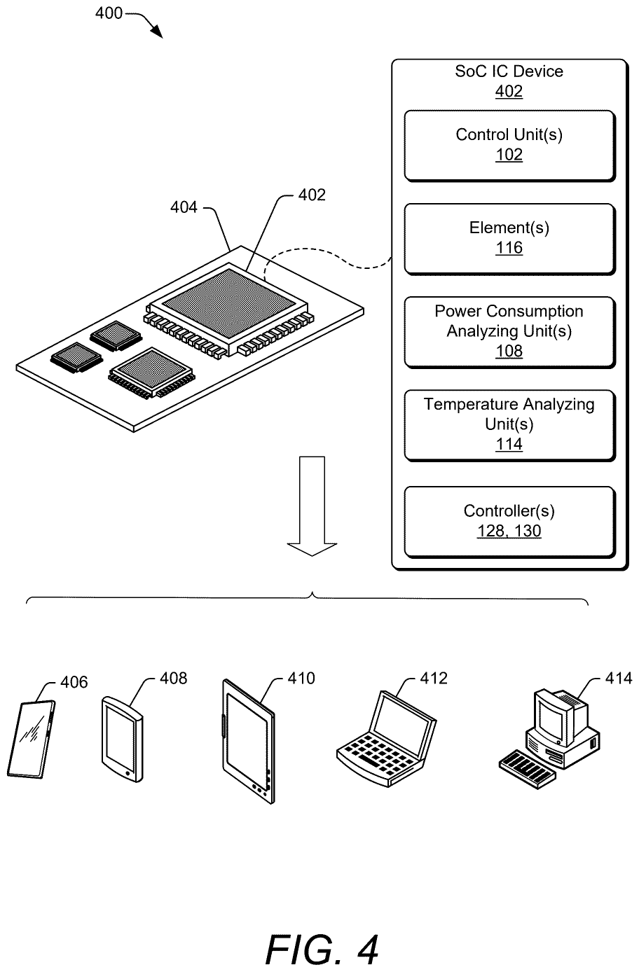

FIG. 4 illustrates an example operating environment 400 in which aspects of a workload-aware control architecture for semiconductor devices can be implemented. As illustrated, an SoC integrated circuit (IC) device 402 may be mounted to a printed circuit board (PCB) 404, which may be included as part of a computing device that implements one or more security protocols. As non-limiting examples, the computing device may be a smartphone 406, a personal digital assistant 408, a tablet 410, a laptop 412, or a workstation 414.

The SoC IC device 402 may include various elements 116 (e.g., GPU, CPU, TPU) that may cause a temperature event (e.g., a sudden increase in temperature) within the SoC IC device 402 due to repeated and/or continued use. For example, a user may repeatedly launch, use, and cancel an application on an electronic device that utilizes the SoC IC device 402. The SoC IC device 402 may include one or more control units 102, power consumption analyzing units 108, temperature analyzing units 114, and controllers 128, 130 configured to control one or more elements 116 of a semiconductor device. The one or more controllers 128, 130 may be configured to thermally control the one or more elements 116 or control the power consumption of the one or more elements 116.

The one or more controllers 128, 130 may control an operating frequency of one or more elements 116 based on revised power target values provided to the controllers 128, 130 from the one or more control units 102. The one or more control units 102 may determine the revised power target values based on power target values provided to the one or more control units 102 from the one or more power consumption analyzing units 108. The one or more power consumption analyzing units 108 may determine the power target values based on power consumption feedback from the one or more elements 116.

The one or more controllers 128, 130 may control an operating frequency of one or more elements 116 based on temperature target values provided to the controller 128, 130 from the one or more control units 102. The one or more control units 102 may determine the temperature target values based on estimated temperature gradients provided to the one or more control units 102 from one or more temperature analyzing units 114. The one or more temperature analyzing units 114 may determine the estimated temperature gradients based on temperature feedback from the one or more elements 116.

Although the SoC IC device 402 is described in the context of a single SoC IC device including the control unit(s) 102, the element(s) 116, the power consumption analyzing unit(s) 108, the temperature analyzing unit(s) 114, and the controller(s) 128, 130, a combination of discrete IC devices may perform the same functions. For example, a discrete processor IC device (e.g., a processor IC device having control unit(s) 102, the element(s) 116, the power consumption analyzing unit(s) 108, the temperature analyzing unit(s) 114, and controller(s) 128, 130) may work in combination with a discrete non-volatile memory IC device having the elements to perform one or more functions described herein.

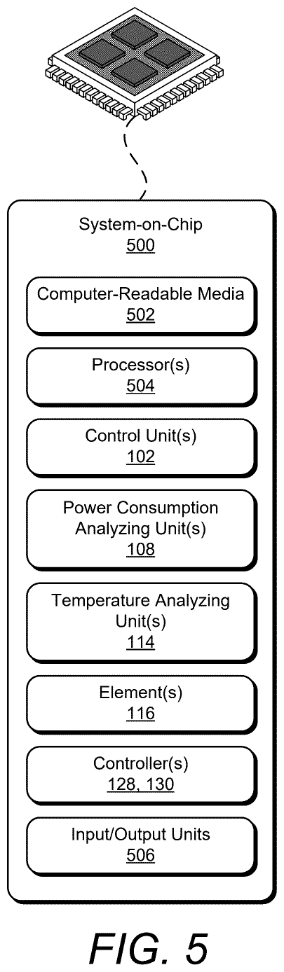

FIG. 5 illustrates an integrated circuit component implemented as an SoC 500 that can implement various aspects of workload-aware control architectures for semiconductor devices. The SoC 500 may be a single chip including components that are fabricated on the same semiconductor substrate. Alternatively, the SoC 500 may be a number of such chips that are epoxied together. The SoC 500 can be implemented in any suitable device, such as a smartphone, a cellular phone, a netbook, a tablet computer, a server, a wireless router, a network-attached storage, a camera, a smart appliance, a printer, a set-top box, or any other suitable type of device. Although described with reference to an SoC, the entities of FIG. 5 may also be implemented as an application-specific integrated circuit (ASIC), a field-programmable gate array (FPGA), or the like.

The SoC 500 can be integrated with electronic circuitry, including the components described in the operating system listed herein. The SoC 500 can also include an integrated data bus (not shown) that couples the various components of the SoC 500 for data communication between the components. The integrated data bus or other components of the SoC 500 may be exposed or accessed through an external port, such as a joint test action group (JTAG) port. For example, components of the SoC 500 may be tested, configured, or programmed (e.g., flashed) through the external port at different stages of manufacture.

In this example, the SoC 500 includes computer-readable media 502, one or more processors 504, control unit(s) 102, power consumption analyzing unit(s) 108, temperature analyzing unit(s) 114, element(s) 116, controller(s) 128 and 130, and I/O units 506. The controller(s) 128 and 130 are configured for thermal control and power consumption of element(s) 116 of a semiconductor device as described herein. The power consumption analyzing unit(s) 108 are configured to analyze power consumption of element(s) 116 of a semiconductor device as described herein. The temperature analyzing unit(s) 114 are configured to predict temperature gradients of element(s) 116 as described herein. The control unit(s) 102 are configured to dynamically generate thermal and power consumption controls based on the workload of the semiconductor device as discussed herein. The computer-readable media 502 may be stored in computer-readable storage media, including one or more non-transitory storage devices such as a random-access memory (RAM), dynamic random access memory (DRAM), non-volatile random access memory (NVRAM), or static random access memory (SRAM), read-only memory (ROM), or flash memory, a hard drive, a solid-state drive (SSD), or any type of media suitable for storing electronic instructions, each coupled with a computer system bus.

The computer-readable media 502 of the SoC 500 may include executable code for the dynamic generation of workload-aware temperature and power consumption controls. One or more of the processor(s) 504 operably coupled to computer-readable storage media having computer-readable media 502 may execute instructions of dynamic thermal control of a semiconductor device.

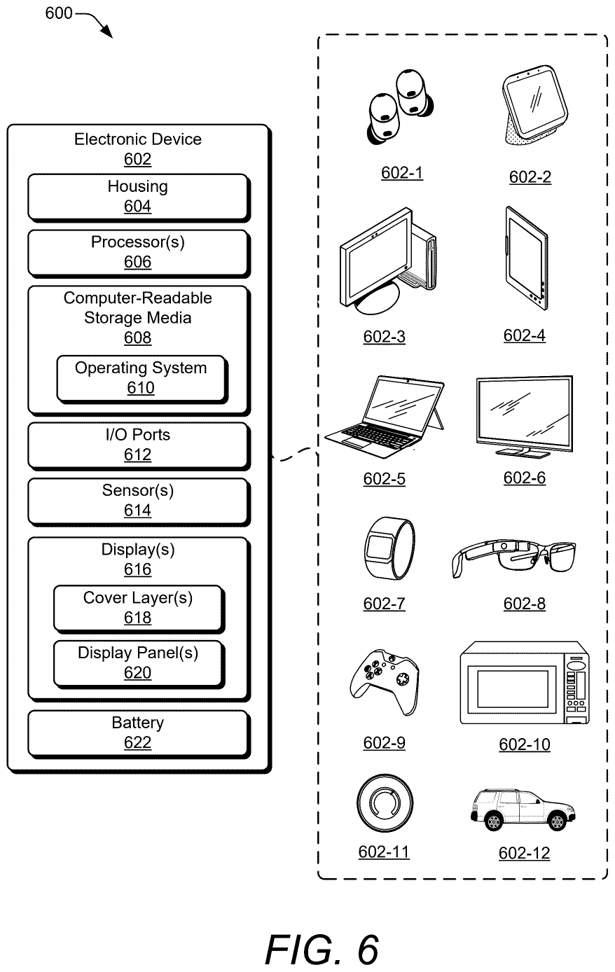

FIG. 6 illustrates an example environment 600 of an example electronic device 602 that includes a workload-aware architecture for semiconductor devices in accordance with one or more implementations. The electronic device 602 may include additional components and interfaces omitted from FIG. 6 for the sake of clarity. The electronic device 602 is illustrated with various non-limiting example electronic devices 602, including wireless earbuds 602-1, a smart display associated with a home-automation and control system 602-2, a desktop computer 602-3, a tablet 602-4, a laptop 602-5, a television 602-6, a computing watch 602-7, computing glasses 602-8, a gaming system 602-9, a microwave 602-10, a smart thermostat interface 602-11, and an automobile having computing capabilities 602-12. Other devices may also be used, such as wired earbuds, a security camera, a trackpad, a drawing pad, a netbook, an e-reader, other forms of home-automation and control systems, a wall display, a virtual-reality headset, another vehicle (e.g., an e-bike or plane), and other home appliances, to name just a few examples. Note that the electronic device 602 may be wearable, non-wearable but mobile, or relatively immobile (e.g., desktops and appliances), all without departing from the scope of the present teachings.

The electronic device 602 includes a housing 604, which defines at least one internal cavity within which one or more of a plurality of electronic components may be disposed. In implementations, a mechanical frame may define one or more portions of the housing 604. As an example, a mechanical frame can include plastic or metallic walls that define portions of the housing 604. In additional implementations, a mechanical frame may support one or more portions of the housing 604. As an example, one or more exterior housing components (e.g., plastic panels) can be attached to the mechanical frame (e.g., a chassis). In so doing, the mechanical frame physically supports the one or more exterior housing components, which define portions of the housing 604. In implementations, the mechanical frame and/or the exterior housing components may be composed of crystalline or non-crystalline solids. In implementations, the housing 604 may be sealed through the inclusion of one or more displays (e.g., at least one display 616), defining at least one internal cavity.

The electronic device 602 may further include one or more processors 606. The processor(s) 606 can include, as non-limiting examples, an SoC, an application processor (AP), a CPU, or a GPU. The processor(s) 606 generally execute commands and processes utilized by the electronic device 602 and an operating system installed thereon. For example, the processor(s) 606 may perform operations to display graphics of the electronic device 602 on the one or more displays 616 and can perform other specific computational tasks.

The electronic device 602 may also include computer-readable storage media (CRM) 608. The CRM 608 may be a suitable storage device configured to store device data of the electronic device 602, user data, and multimedia data. The CRM 608 may store an operating system 610 that generally manages hardware and software resources (e.g., the applications) of the electronic device 602 and provides common services for applications stored on the CRM 608. The operating system 610 and the applications are generally executable by the processor(s) 606 to enable communications and user interaction with the electronic device 602. One or more processors 606, such as a GPU, perform operations to display graphics of the electronic device 602 on the one or more displays 616 and can perform other specific computational tasks. The processors 606 can be single-core or multiple-core processors.

The electronic device 602 may also include input/output (I/O) ports 612. The I/O ports 612 allow the electronic device 602 to interact with other devices or users. The I/O ports 612 may include any combination of internal or external ports, such as universal serial bus (USB) ports, audio ports, serial advanced technology attachment (SATA) ports, peripheral component interconnect standard (PCI)-express based ports or card-slots, secure digital input/output (SDIO) slots, and/or other legacy ports.

The electronic device 602 may further include one or more sensors 614. The sensor(s) 614 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the electronic device 602 includes one or more of a front-facing sensor(s) and a rear-facing sensor(s). An element 116 of the semiconductor device may be the various components of the electronic device 602. For example, the element 116 may be the processor(s) 606, the computer-readable storage media 608, the I/O ports 612, the sensor(s) 614, the display(s) 616, a battery 622, or the like. The operating system 610 and/or various processor(s) 606 of the electronic device 602 include operating instructions to enable a workload-aware control architecture to control the operating frequency of various components of the electronic device 602 by the dynamic generation of workload-aware control policies.

The electronic device 602 may include the one or more displays 616, one or more cover layers 618, and one or more display panels 620. The cover layer(s) 618 may be implemented as any of a variety of transparent materials including polymers (e.g., plastic, acrylic) or glasses.

The electronic device 602 further includes a battery 622. In implementations, the battery 622 is a rechargeable battery that is configured to store and supply electrical energy. The rechargeable battery 622 may be any suitable rechargeable battery, such as a lithium-ion (Li-ion) battery.

### Example Methods

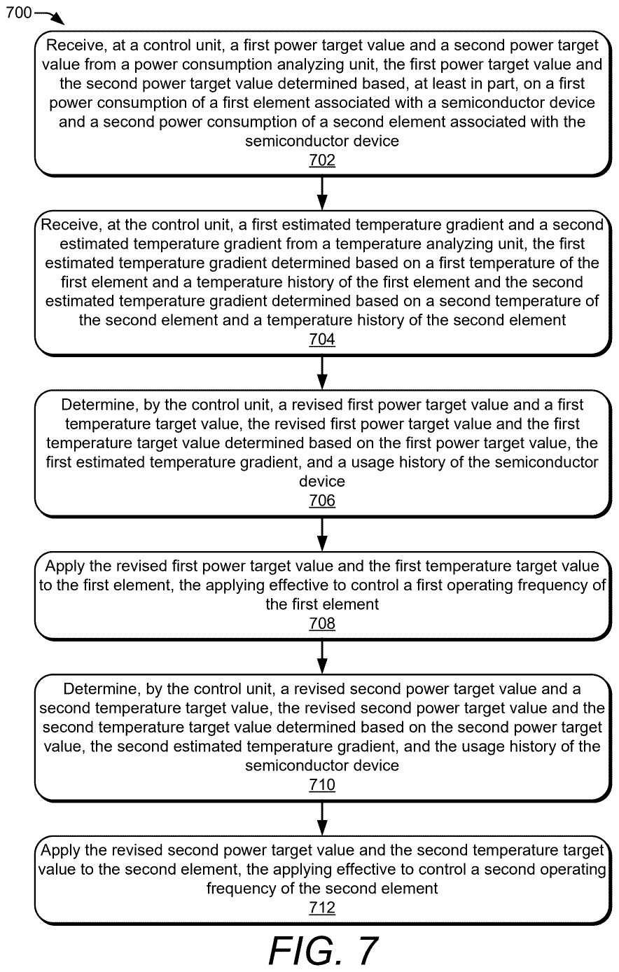

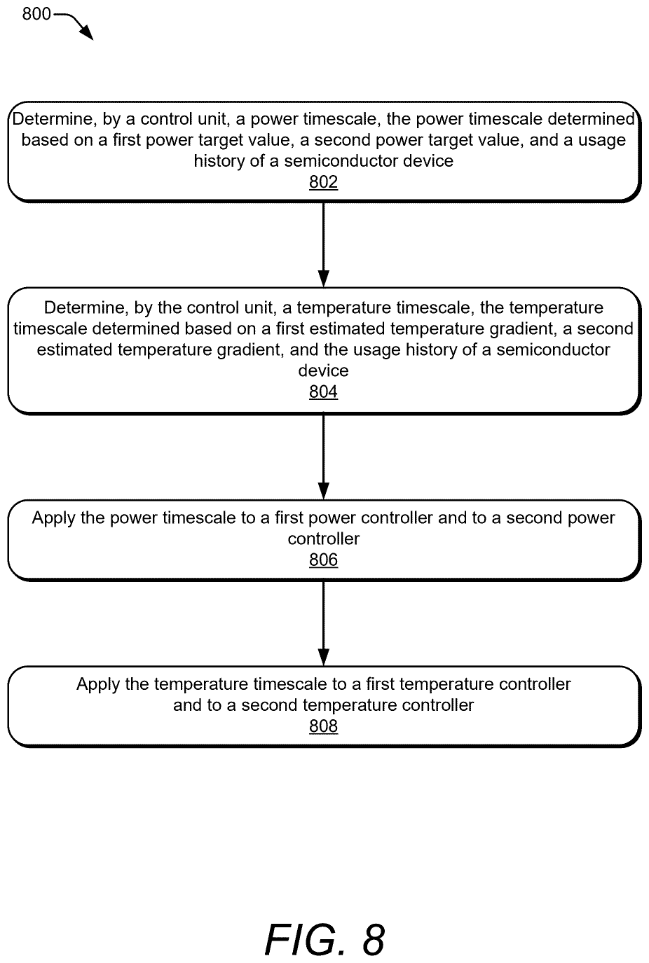

Example methods are described below with reference to the flowcharts of FIG. 7 and FIG. 8. Although example method aspects are described separately below, they may be implemented together in any combination or permutation.

FIG. 7 is a flowchart that illustrates a method 700 of a workload-aware control architecture for semiconductor devices, which includes operations 702 through 712. At step 702, a first power target value and a second power target value are received at a control unit from a power consumption analyzing unit, the first power target value and the second power target value determined based, at least in part, on a first power consumption of a first element associated with a semiconductor device and a second power consumption of a second element associated with the semiconductor device. For example, a control unit (e.g., control unit 102) receives a first power target value (e.g., first power target value 104) and a second power target value (e.g., second power target value 106) from a power consumption analyzing unit (e.g., power consumption analyzing unit 108). The first power target value (e.g., first power target value 104) is based, at least in part, on a first power consumption value (e.g., a first power consumption value 118-1) of a first element (e.g., first element 116-1). The second power target value (e.g., second power target value 106) is based, at least in part, on a second power consumption value (e.g., a second power consumption value 118-2) of a second element (e.g., second element 116-2).

At step 704, a first estimated temperature gradient and a second estimated temperature gradient are received at the control unit from a temperature analyzing unit, the first estimated temperature gradient and the second estimated temperature gradient determined based, at least in part, on a first temperature and a temperature history of the first element and a second temperature and a temperature history of the second element. For example, the control unit (e.g., control unit 102) receives a first estimated temperature gradient (e.g., first estimated temperature gradient 110) and a second estimated temperature gradient (e.g., second estimated temperature gradient 112) from a temperature analyzing unit (e.g., temperature analyzing unit 114). The first estimated temperature gradient (e.g., first estimated temperature gradient 110) is based, at least in part, on a first temperature value (e.g., a first temperature value 120-1) and a first temperature history (e.g., first temperature history 122-1) of the first element (e.g., first element 116-1). The second estimated temperature gradient (e.g., second estimated temperature gradient 112) is based, at least in part, on a second temperature value (e.g., second temperature value 120-2) and a second temperature history (e.g., second temperature history 122-2) of the second element (e.g., second element 116-2).

At step 706, a first revised power target value and a first temperature target value are determined by the control unit, the first revised power target value and the first temperature target value determined based on the first power target value, the first estimated temperature gradient, and a usage history of the semiconductor device. For example, the control unit (e.g., control unit 102) determines a first revised power target value (e.g., first revised power target value 104-1) and a first temperature target value (e.g., first temperature target value 124-1) based on the first power target value (e.g., first power target value 104) received from the power consumption analyzing unit (e.g., power consumption analyzing unit 108), the first estimated temperature gradient (e.g., first estimated temperature gradient 110) received from the temperature analyzing unit (e.g., temperature analyzing unit 114), and a usage history (e.g., usage history 120). The usage history (e.g., usage history 120) may be provided to the control unit (e.g., control unit 102) by a machine-learned model or by artificial intelligence. The usage history (e.g., usage history) may include a present workload and/or a prior workload history of the semiconductor device.

At step 708, the first revised power target value and the first temperature target value are applied to the first element, the applying effective to control a first operating frequency of the first element. For example, the first revised power target value (e.g., first revised power target value 104-1) and the first temperature target value (e.g., first temperature target value 124-1) are applied to the first element (e.g., first element 116-1). The first revised power target value (e.g., first revised power target value 104-1) and the first temperature target value (e.g., first temperature target value 124-1) may be applied directly to the first element (e.g., first element 116-1). In other aspects, the first revised power target value (e.g., first revised power target value 104-1) may be applied to the first element (e.g., first element 116-1) by a first power controller (e.g., first power controller 128-1) and the first temperature target value (e.g., first temperature target value 124-1) may be applied to the first element (e.g., first element 116-1) by a first temperature controller (e.g., first temperature controller 130-1), the applying of the first temperature target value (e.g., first temperature target value 124-1) and the first revised power target value (e.g., first revised power target value 104-1) effective to control a first operating frequency of the first element (e.g., first element 116-1).

At step 710, a second revised power target value and a second temperature target value are determined by the control unit, the second revised power target value and the second temperature target value determined based on the second power target value, the second estimated temperature gradient, and the usage history of the semiconductor device. For example, the control unit (e.g., control unit 102) determines a second revised power target value (e.g., second revised power target value 106-1) and a second temperature target value (e.g., second temperature target value 124-2) based on the second power target value (e.g., second power target value 106) received from the power consumption analyzing unit (e.g., power consumption analyzing unit 108), the second estimated temperature gradient (e.g., second estimated temperature gradient 112) received from the temperature analyzing unit (e.g., temperature analyzing unit 114), and the usage history (e.g., usage history 120). The usage history (e.g., usage history 120) may be provided to the control unit (e.g., control unit 102) by a machine-learned model or by artificial intelligence. The usage history (e.g., usage history 120) may include a present workload and/or a prior workload history of the semiconductor device.

At step 712, the second revised power target value and the second temperature target value are applied to the second element, the applying effective to control a second operating frequency of the second element. For example, the second revised power target value (e.g., second revised power target value 106-1) and the second temperature target value (e.g., second temperature target value 124-2) are applied to the second element (e.g., second element 116-2). The second revised power target value (e.g., second revised power target value 106-1) and the second temperature target value (e.g., second temperature target value 124-2) may be applied directly to the second element (e.g., second element 116-2). In other aspects, the second revised power target value (e.g., second revised power target value 106-1) may be applied to the second element (e.g., second element 116-2) by a second power controller (e.g., second power controller 128-2) and the second temperature target value (e.g., second temperature target value 124-2) may be applied to the second element (e.g., second element 116-2) by a second temperature controller (e.g., second temperature controller 130-2), the applying of the second temperature target value (e.g., second temperature target value 124-2) and the second revised power target value (e.g., second revised power target value 106-1) effective to control a second operating frequency of the second element (e.g., second element 116-2).

FIG. 8 is a flowchart that illustrates a method 800 of a workload-aware control architecture for semiconductor devices, which includes operations 802 through 808. The method 800 of a workload-aware control architecture for semiconductor devices may be a continuation of the method 700 of FIG. 7.

At step 802, a power timescale is determined by a control unit, the power timescale determined based on a first power target value, a second power target value, and a usage history of a semiconductor device. For example, a control unit (e.g., control unit 102) determines a power timescale. The power timescale may be determined based on a first power target value (e.g., first power target value 104), a second power target value (e.g., second power target value 106), and a usage history (e.g., usage history 120) of a semiconductor device. The power timescale may determine how often (e.g., rate) a power controller (e.g., power controller 128) monitors power consumption by an element (e.g., first element 116-1, second element 116-2) and/or how often the power controller (e.g., power controller 128) should control the power consumption by the element (e.g., first element 116-1, second element 116-2) by applying a power-based operating frequency (e.g., first power-based operating frequency 132-1, second power-based operating frequency 132-2) to the element (e.g., first element 116-1, second element 116-2).

At step 804, a temperature timescale is determined by the control unit, the temperature timescale determined based on a first estimated temperature gradient, a second estimated temperature gradient, and the usage history of the semiconductor device. For example, the control unit (e.g., control unit 102) determines a temperature timescale. The temperature timescale may be determined based on a first estimated temperature gradient (e.g., first estimated temperature gradient 110), a second estimated temperature gradient (e.g., second estimated temperature gradient 112), and the usage history (e.g., usage history 120) of the semiconductor device. The temperature timescale may determine how often a temperature controller (e.g., temperature controller 130) monitors the temperature of an element (e.g., first element 116-1, second element 116-2) and/or how often the temperature controller (e.g., temperature controller 130) should control the temperature of the element (e.g., first element 116-1, second element 116-2) by applying a temperature-based operating frequency (e.g., first temperature-based operating frequency 134-1, second temperature-based operating frequency 134-2) to the element (e.g., first element 116-1, second element 116-2).

At step 806, the power timescale is applied to a first power controller and to a second power controller. For example, the power timescale is applied to a first power controller (e.g., first power controller 128-1) and is applied to a second power controller (e.g., second power controller 128-2). As discussed above, the power timescale may determine how often the power controllers (e.g., first power controller 128-1, second power controller 128-2) monitor and/or control power consumption by an element (e.g., first element 116-1, second element 116-2).

At step 808, the temperature timescale is applied to a first temperature controller and to a temperature power controller. For example, the temperature timescale is applied to a first temperature controller (e.g., first temperature controller 130-1) and is applied to a second temperature controller (e.g., second temperature controller 130-2). As discussed above, the temperature timescale may determine how often the temperature controllers (e.g., first temperature controller 130-1, second temperature controller 130-2) monitor and/or control the temperature of an element (e.g., first element 116-1, second element 116-2).

For the methods described herein and the associated flowchart(s) and flow diagram(s), the orders in which operations are shown and/or described are not intended to be construed as a limitation. Instead, any number or combination of the described method operations can be combined in any order to implement a given method or an alternative method, including by combining operations from the flowchart or diagram and the earlier-described techniques into one or more methods. Operations may also be omitted from or added to the described methods. Further, described operations can be implemented in fully or partially overlapping manners.

### Conclusion

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for workload-aware control architectures for semiconductor devices have been described in language specific to certain features and/or methods, the subject of the appended claims is not necessarily limited to the specific features or methods described. Rather, the specific features and methods are disclosed as example implementations for workload-aware control architectures for semiconductor devices.

What is claimed is:

1. A method comprising:
receiving, at a control unit, a first power target value and a second power target value from a power consumption analyzing unit, the first power target value and the second power target value determined based, at least in part, on a first power consumption of a first element associated with a semiconductor device and a second power consumption of a second element associated with the semiconductor device;
receiving, at the control unit, a first estimated temperature gradient and a second estimated temperature gradient from a temperature analyzing unit, the first estimated temperature gradient determined based on a first temperature of the first element and a temperature history of the first element and the second estimated temperature gradient determined based on a second temperature of the second element and a temperature history of the second element;
determining, by the control unit, a first revised power target value and a first temperature target value, the first revised power target value and the first temperature target value determined based on the first power target value, the first estimated temperature gradient, and a usage history of the semiconductor device;
applying the first revised power target value and the first temperature target value to the first element, the applying effective to control a first operating frequency of the first element;
determining, by the control unit, a second revised power target value and a second temperature target value, the second revised power target value and the second temperature target value determined based on the second power target value, the second estimated temperature gradient, and the usage history of the semiconductor device; and
applying the second revised power target value and the second temperature target value to the second element, the applying effective to control a second operating frequency of the second element.

2. The method of claim 1, wherein a machine-learned model determines the usage history of the semiconductor device.

3. The method of claim 1, wherein artificial intelligence determines the usage history of the semiconductor device.

4. The method of claim 1, further comprising:
receiving, at the power consumption analyzing unit, a first power consumption of the first element and a second power consumption of the second element; and
determining a metric based on the first power consumption and the second power consumption, wherein the metric is applied to the first power consumption and the second power consumption to determine the first power target value and the second power target value.

5. The method of claim 4, further comprising:
receiving, at the temperature analyzing unit, the first temperature of the first element, wherein the temperature analyzing unit determines the first estimated temperature gradient based on the first temperature and the temperature history of the first element; and
receiving, at the temperature analyzing unit, the second temperature of the second element, wherein the temperature analyzing unit determines the second estimated temperature gradient based on the second temperature and the temperature history of the second element.

6. The method of claim 1, further comprising:
receiving the first power consumption of the first element at a first power controller coupled with the first element; and
receiving the first temperature of the first element at a first temperature controller coupled with the first element;
wherein:
applying the first revised power target value comprises applying the first revised power target value to the first power controller, the first power controller determining a first power-based operating frequency based on the first revised power target value and the first power consumption and applying the first power-based operating frequency to the first element;
applying the first temperature target value comprises applying the first temperature target value to the first temperature controller, the first temperature controller determining a first temperature-based operating frequency based on the first temperature target value and the first temperature and applying the first temperature-based operating frequency to the first element; and
the first operating frequency of the first element is a lesser of the first power-based operating frequency and the first temperature-based operating frequency.

7. The method of claim 6, further comprising:
receiving the second power consumption of the second element at a second power controller coupled with the second element; and
receiving the second temperature of the second element at a second temperature controller coupled with the second element;
wherein:
applying the second revised power target value comprises applying the second revised power target value to the second power controller, the second power controller determining a second power-based operating frequency based on the second revised power target value and the second power consumption and applying the second power-based operating frequency to the second element;
applying the second temperature target value comprises applying the second temperature target value to the second temperature controller, the second temperature controller determining a second temperature-based operating frequency based on the second temperature target value and the second temperature and applying the second temperature-based operating frequency to the second element; and
the second operating frequency of the second element is the lesser of the second power-based operating frequency and the second temperature-based operating frequency.

8. The method of claim 7, further comprising:
determining, by the control unit, a power timescale, the power timescale determined based on the first power target value, the second power target value, and the usage history of the semiconductor device;
determining, by the control unit, a temperature timescale, the temperature timescale determined based on the first estimated temperature gradient, the second estimated temperature gradient, and the usage history of the semiconductor device;
applying the power timescale to the first power controller and to the second power controller; and
applying the temperature timescale to the first temperature controller and to the second temperature controller.

9. The method of claim 8, wherein:
applying the power timescale to the first power controller and to the second power controller determines a first rate of the first power controller and the second power controller; and
applying the temperature timescale to the first temperature controller and to the second temperature controller determines a second rate of the first temperature controller and the second temperature controller.

10. The method of claim 9, wherein:
the first rate sets a monitoring time period or controller time period of the first power controller and the second power controller; and
the second rate sets a monitoring time period or controller time period of the first temperature controller and the second temperature controller.

11. A system comprising:
a first element of a semiconductor device, the first element having a first power consumption and a first temperature;
a second element of the semiconductor device, the second element having a second power consumption and a second temperature;
a power consumption analyzing unit coupled to the first element and the second element, the power consumption analyzing unit configured to determine a metric based on the first power consumption and the second power consumption, the metric applied to the first power consumption and the second power consumption to determine a first power target value and a second power target value;
a temperature analyzing unit coupled to the first element and the second element, the temperature analyzing unit configured to determine a first estimated temperature gradient and a second estimated temperature gradient, the first estimated temperature gradient determined based on a first temperature of the first element and a temperature history of the first element and the second estimated temperature gradient determined based on a second temperature of the second element and a temperature history of the second element;
a control unit coupled with the power consumption analyzing unit and the temperature analyzing unit, the control unit configured to determine a first revised power target value and a first temperature target value based on the first power target value, the first estimated temperature gradient, and a usage history of the semiconductor device and configured to determine a second revised power target value and a second temperature target value based on the second power target value, the second estimated temperature gradient, and the usage history of the semiconductor device;
a first temperature controller coupled with the control unit and the first element, the first temperature controller configured to apply a first temperature-based operating frequency to the first element based on the first temperature and the first temperature target value;
a first power controller coupled with the control unit and the first element, the first power controller configured to apply a first power-based operating frequency to the first element based on the first power consumption and the first revised power target value;
a second temperature controller coupled with the control unit and the second element, the second temperature controller configured to apply a second temperature-based operating frequency to the second element based on the second temperature and the second temperature target value; and
a second power controller coupled with the control unit and the second element, the second power controller configured to apply a second power-based operating frequency to the second element based on the second power consumption and the second revised power target value.

12. The system of claim 11, wherein:
the first element is configured to operate at a first operating frequency, the first operating frequency being a lesser of the first temperature-based operating frequency and the first power-based operating frequency; and
the second element is configured to operate at a second operating frequency, the second operating frequency being a lesser of the second temperature-based operating frequency and the second power-based operating frequency.

13. The system of claim 11, further comprising:
a first controller coupled between the first element and the first temperature controller and first power controller, the first controller configured to cause the first element to operate at a first operating frequency, the first operating frequency being a lesser of the first temperature-based operating frequency and the first power-based operating frequency; and
a second controller coupled between the second element and the second temperature controller and second power controller, the second controller configured to cause the second element to operate at a second operating frequency, the second operating frequency being a lesser of the second temperature-based operating frequency and the second power-based operating frequency.

14. The system of claim 11, the power consumption analyzing unit further comprising:
a weighting unit coupled with the first element and the second element, the weighting unit configured to receive the first power consumption and the second power consumption and to determine the metric by weighting the first power consumption and the second power consumption; and
a target determination unit coupled with the weighting unit, the first element, the second element, and the control unit, the target determination unit configured to receive the first power consumption and the second power consumption and to generate the first power target value and the second power target value by applying the metric to the first power consumption and the second power consumption.

15. The system of claim 14, wherein the weighting unit determines the metric by:
averaging the first power consumption and the second power consumption; or
determining whether the first power consumption or the second power consumption exceeds a predetermined threshold and applying a first weight to any power consumption that exceeds the predetermined threshold and applying a second weight to any power consumption that is below the predetermined threshold, the second weight being less than the first weight.

16. The system of claim 11, wherein the control unit is configured to:
determine a first power timescale, the first power timescale determined based on the first power target value and the usage history of the semiconductor device;
determine a second power timescale, the second power timescale determined based on the second power target value and the usage history of the semiconductor device;
determine a first temperature timescale, the first temperature timescale determined based on the first estimated temperature gradient and the usage history of the semiconductor device;
determine a second temperature timescale, the second temperature timescale determined based on the second estimated temperature gradient and the usage history of the semiconductor device;
apply the first power timescale to the first power controller, the first power timescale determining a first rate at which the first power controller applies the first power-based operating frequency to the first element;
apply the second power timescale to the second power controller, the second power timescale determining a second rate at which the first temperature controller applies the second power-based operating frequency to the second element;
apply the first temperature timescale to the first temperature controller, the first temperature timescale determining a third rate at which the second power controller applies the first temperature-based operating frequency to the first element; and
apply the second temperature timescale to the second temperature controller, the second temperature timescale determining a fourth rate at which the second temperature controller applies the second temperature-based operating frequency to the second element.

17. A system comprising:
a first element of a semiconductor device, the first element having a first power consumption and a first temperature;
a second element of the semiconductor device, the second element having a second power consumption and a second temperature;
a power consumption analyzing unit coupled to the first element and the second element, the power consumption analyzing unit configured to determine a metric based on the first power consumption and the second power consumption, the metric applied to the first power consumption and the second power consumption to determine a first power target value and a second power target value;
a temperature analyzing unit coupled to the first element and the second element, the temperature analyzing unit configured to determine a first estimated temperature gradient and a second estimated temperature gradient, the first estimated temperature gradient determined based on a first temperature of the first element and a temperature history of the first element and the second estimated temperature gradient determined based on a second temperature of the second element and a temperature history of the second element;
a control unit coupled with the power consumption analyzing unit and the temperature analyzing unit, the control unit configured to:
(i) determine a first revised power target value and a first temperature target value based on the first power target value, the first estimated temperature gradient, and a usage history of the semiconductor device; and
(ii) determine a second revised power target value and a second temperature target value based on the second power target value, the second estimated temperature gradient, and the usage history of the semiconductor device;
a temperature controller coupled with the control unit, the first element, and the second element, the temperature controller configured to apply a first temperature-based operating frequency to the first element based on the first temperature and the first temperature target value and to apply a second temperature-based operating frequency to the second element based on the second temperature and the second temperature target value; and
a power controller coupled with the control unit, the first element, and the second element, the power controller configured to apply a first power-based operating frequency to the first element based on the first power consumption and the first revised power target value and to apply a second power-based operating frequency to the second element based on the second power consumption and the second revised power target value.

18. The system of claim 17, wherein:
the first element is configured to operate at a first operating frequency, the first operating frequency being a lesser of the first temperature-based operating frequency and the first power-based operating frequency; and
the second element is configured to operate at a second operating frequency, the second operating frequency being a lesser of the second temperature-based operating frequency and the second power-based operating frequency.

19. The system of claim 18, wherein the control unit is configured to:
determine a power timescale, the power timescale determined based on the first power target value, the second power target value, and the usage history of the semiconductor device;
determine a temperature timescale, the temperature timescale determined based on the first estimated temperature gradient, the second estimated temperature gradient, and the usage history of the semiconductor device;
apply the power timescale to the power controller; and
apply the temperature timescale to the temperature controller.

20. The system of claim 19, wherein:
the power timescale determines a first rate of the power controller, the first rate being a first time period in which the power controller monitors or controls power consumption of the first element and power consumption of the second element; and
the temperature timescale determines a second rate of the temperature controller, the second rate being a second time period in which the temperature controller monitors or controls a temperature of the first element and a temperature of the second element.
